(19) United States
(12) Patent Application Publication
(10) Pub. No.: US 2013/0220683 A1
(43) Pub. Date: Aug. 29, 2013

(54) PRINTED CIRCUIT BOARD AND METHOD FOR MANUFACTURING PRINTED CIRCUIT BOARD

(71) Applicant: ZONG-QING CAI, Shenzhen City (CN)

(72) Inventor: ZONG-QING CAI, Shenzhen City (CN)

(73) Assignees: ZHEN DING TECHNOLOGY CO., LTD., Taoyuan (TW); HONG HENG SHENG ELECTRONICAL TECHNOLOGY (HuaiAn)Co.,Ltd, Huai An City (CN)

(21) Appl. No.: 13/537,073

(22) Filed: Jun. 29, 2012

(30) Foreign Application Priority Data
Feb. 24, 2012 (CN) 201210043029.9

(51) Int. Cl. H05K 1/09; H05K 3/12; H05K 3/02

(52) U.S. Cl. 174/257; 29/847

(57) ABSTRACT

A printed circuit board includes an inner substrate, a stuffing layer, an adhesive layer and a plurality of second copper trace layer. The inner substrate includes an insulating layer and an copper trace layer formed on a surface of the insulating layer. The first surface includes a low copper density region. In the low copper density region, the area of first surface covered by the copper trace layer is less than 60 percent of the area of the low copper density region. The stuffing layer is only formed on the first inner substrate in the region. The present disclosure also provides a method for manufacturing the printed circuit board.

### BACKGROUND

1. Technical Field

The present disclosure generally relates to printed circuit boards (PCBs), and particularly, relates to a printed circuit board and a method for manufacturing the printed circuit board.

2. Description of Related Art

To accommodate development of miniaturized electronic products with multiple function, printed circuit boards are widely used due to their special characteristics such as lightness and high-density interconnectability.

Printed circuit boards are manufactured using a typical sheet-by-sheet process. First, a core substrate is provided and an inner electrically conductive pattern is formed in the core substrate. The inner electrically conductive pattern includes a plurality of traces. Second, an adhesive layer and a first electrically conductive layer such as copper foil are laminated on the core substrate. Third, an electrically conductive pattern is formed in the first electrically conductive layer. However, the inner electrically conductive pattern generally includes a first low copper density region having less traces and a second low copper density region having more traces. When the adhesive layer is laminated on the first and second low copper density regions at a high temperature and a high pressure, the adhesive flows into a gap between the neighbor traces in the first low copper density region. After lamination, a thickness of the adhesive layer in the first low copper density region is smaller than that of the adhesive layer in the second low copper density region, thus the printed circuit board is not flat.

What is needed, therefore, is a printed circuit board and a method for manufacturing the same which overcomes the above-described problems.

### BRIEF DESCRIPTION OF THE DRAWINGS

Many aspects of the present embodiment can be better understood with reference to the following drawings. The components in the drawings are not necessarily drawn to scale, the emphasis instead being placed upon clearly illustrating the principles of the present embodiment. Moreover, in the drawings, like reference numerals designate corresponding parts through out the several views.

FIG. 1 is a cross-sectional view of a substrate including an insulating layer, a first electrically conductive layer and a second electrically conductive layer in accordance with a first embodiment.

FIG. 2 is a cross-sectional view of an inner substrate obtained by removing part of the first electrically conductive layer in FIG. 1 to form a plurality first copper trace layer and removing part of the second electrically conductive layer in FIG. 1 to a plurality of second copper trace layer.

FIG. 3 is a top view of the inner substrate of FIG. 2, the inner substrate including a first low copper density region, in the first low copper density region an area of the insulating layer covered by the first copper trace layer being less than 60 percent of an entire area of the first low copper density region.

FIG. 4 is similar to FIG. 2, but showing a first stuffing layer formed on the first low copper density region and a second stuffing layer formed on a second low copper density region of the inner substrate.

FIG. 5 is similar to FIG. 4, but showing a first copper film and a first adhesive layer sequentially laminated on one side of the inner substrate of FIG. 4, and a second copper film and a second adhesive layer sequentially laminated on an opposite side of the inner substrate.

FIG. 6 is similar to FIG. 5, but showing a number of third copper trace layer formed by removing part of first copper film, and a number of fourth copper trace layer formed by removing part of second copper film.

### DETAILED DESCRIPTION

Embodiments are now described in detail and with reference to the drawings.

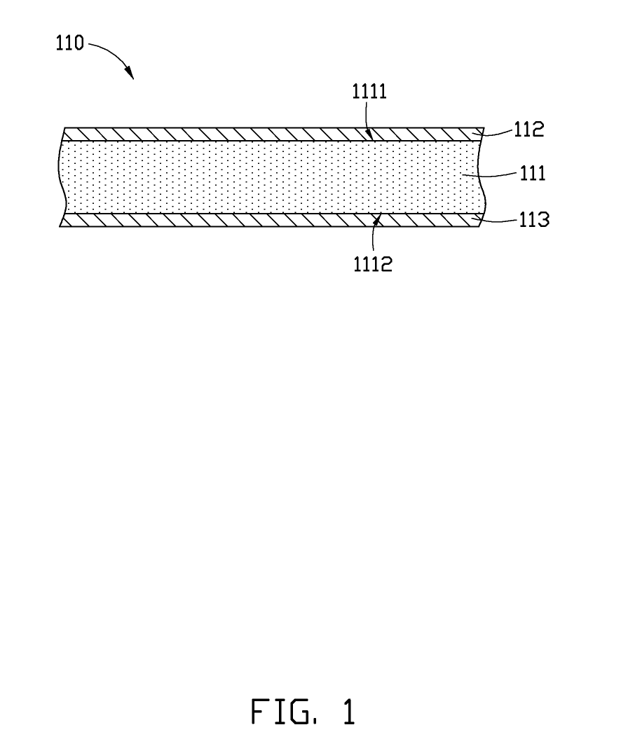

FIGS. 1-6, is an illustrated embodiment of a method for manufacturing a PCB. The method includes the following steps.

In Step 1, referring to FIG. 1, a substrate 110 is provided.

In the illustrative embodiment, the substrate 110 includes a first insulating layer 111, a first electrically conductive layer 112 and a second electrically conductive layer 113. The insulating layer 111 includes a first surface 1111 and a second surface 1112 opposite to the first surface 1111. The first electrically conductive layer 112 is formed on the first surface 1111. The second electrically conductive layer 113 is formed on the second surface 1112. A thickness of the first and second electrically conductive layers 112, 113 can be in the range of about 40 micrometers to 50 micrometers.

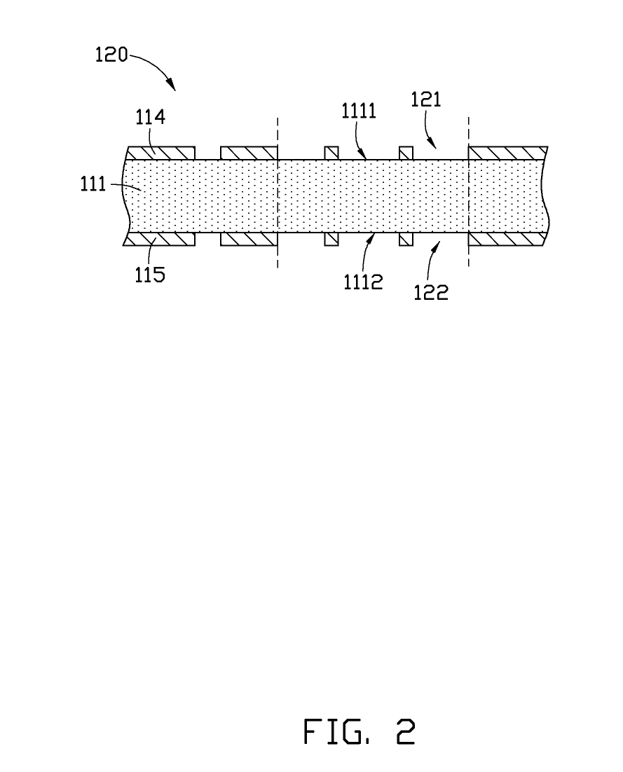

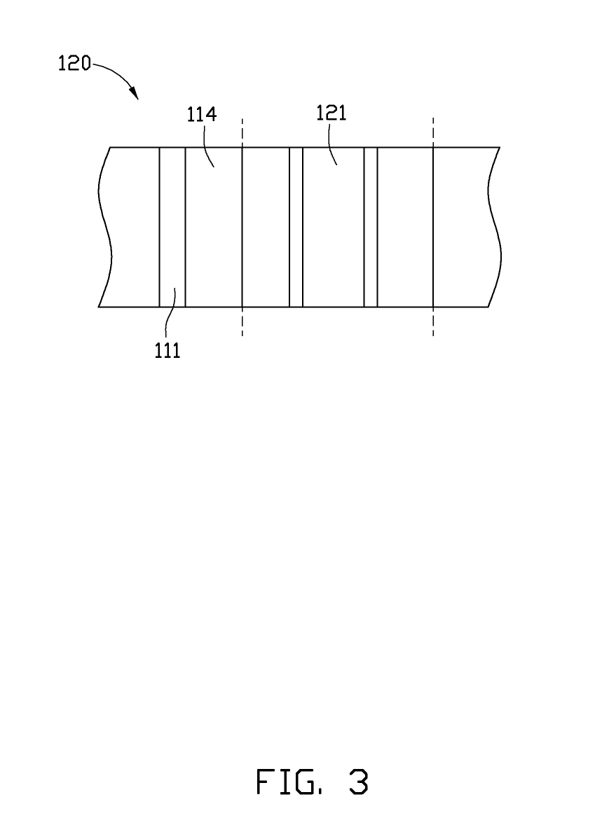

In Step 2, referring to FIGS. 2 and 3, a first copper trace layer 114 is formed by removing part of the first electrically conductive layer 112, and a second copper trace layer 115 is formed by removing part of the second electrically conductive layer 113, thus an inner layer substrate 120 comprising the first insulating layer 111, the first copper trace layer 114 and the second copper trace layer 115 is obtained.

The first copper trace layer 114 and the second copper trace layer 115 can be formed by using a photolithography process and an etching process. The first surface 1111 includes a first low copper density region 121. The second surface 1112 includes a second low copper density region 122. In this embodiment, the first low copper density region 121 and second low copper density region 122 are limited by two dashed lines in FIG. 2. The first low copper density region 121 and second low copper density region 122 is arranged between the two dashed lines. In the first low copper density region 121, an area of the insulating layer 111 covered by the first copper trace layer 114 is less than 60 percent of an entire area of the first low copper density region 121. In other words, when forming the first copper trace layer 114 on the first low copper density region 121, more than 40 percent of the first electrically conductive layer 112 on the first low copper density region 121 is removed. In the second low copper density region 122, an area of the insulating layer 111 covered by the second copper trace layer 115 is less than 60 percent of an entire area of the second low copper density region 122. In another words, when forming the second copper trace layer 115 on the second low copper density region 122, more than 40 percent of the second electrically layer 113 on the second low copper density region 122 is removed.

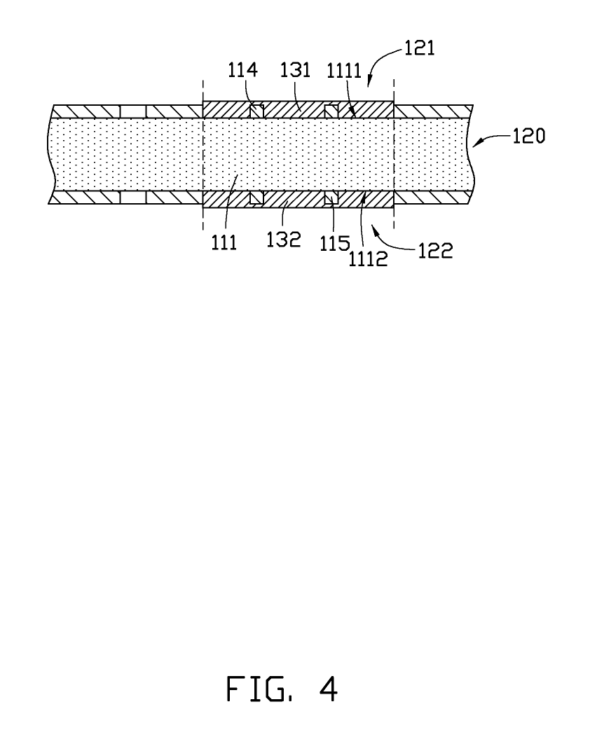

In Step 3, referring to FIG. 4, a first stuffing layer 131 is formed on the first surface 1111 exposed to the gaps between the first copper trace layer 114 and surfaces of the first copper trace layer 114 in the first low copper density region 121, and a second stuffing layer 132 is formed on the second surface 1112 exposed to the gaps between the second copper trace layer 115 and surfaces of the second copper trace layer 115 in the second low copper density region 122.

In an alternative embodiment, to reinforce the combination of the first, second stuffing layer 131, 132 and the inner substrate 120, before forming the first stuffing layer 131 and the second stuffing layer 132, the first surface 1111 is exposed to the gaps between the first copper trace layer 114, the surface of the first copper trace layer 114, the second surface 1112 is exposed to the gaps between the second copper trace layer 115, and the surfaces of the second copper trace layer 115 can be roughened by black oxidation.

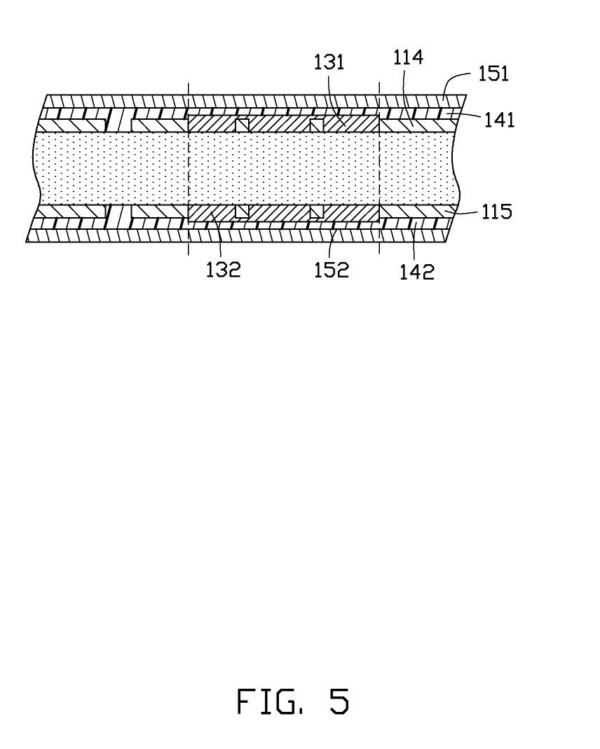

The first stuffing layer 131 and the second stuffing layer 132 are formed by printing insulating ink. The thickness of the first stuffing layer 131 formed on the first surface 1111 of the insulating layer 111 can be substantially equal to that of the first electrically conductive layer 112. The thickness of the first stuffing layer 131 formed on the first surface 1111 of the insulating layer 111 can also be a little more than that of the first electrically conductive layer 112, thus the first stuffing layer 131 can cover the entire first copper trace layer 114 and the entire first surface 1111 of the insulating layer 111 in the first low copper density region 121. However, a thickness of the first stuffing layer 131 formed on the first copper trace layer 114 is less than that of the adhesive layer (an adhesive layer in FIG. 5) to be formed in the following steps. The thickness of the first stuffing layer 131 formed on the first surface 1111 of the insulating layer 111 also may be a slightly less than that of the first electrically conductive layer 112, thus the first stuffing layer 131 is only formed on the first surface 111 of the insulating layer 111 exposed to the gaps between the first electrically traces 114 in the first low copper density region 121.

The thickness of the second stuffing layer 132 formed on the second surface 1112 of the insulating layer 111 can be substantially equal to that of the second electrically conductive layer 113. The thickness of the second stuffing layer 131 formed on the second surface 1111 of the insulating layer 111 can also be a slight more than that of the second electrically conductive layer 113, thus the second stuffing layer 132 can cover the second copper trace layer 115 and the entire second surface 1115 of the insulating layer 111 in the second low copper density region 122. However, a thickness of the second stuffing layer 132 formed on the second copper trace layer 115 is slight less than that of the adhesive layer (an adhesive layer in FIG. 5) to be formed in the following steps. The thickness of the second stuffing layer 132 formed on the second surface 1112 of the insulating layer 111 also may be a slightly less than that of the second electrically conductive layer 113, thus the second stuffing layer 132 is only formed on the second surface 1112 of the insulating layer 111 exposed to the gaps between the second copper traces 115 in the first low copper density region 122.

In Step 4, referring to FIG. 5, a first adhesive layer 141 is laminated on the first electrically conductive circuit 114 and the first stuffing layer 131 of the inner layer substrate 120, a first copper film 151 is laminated on the first adhesive layer 141, the first adhesive layer 141 is arranged between the first copper film 151 and the inner layer substrate 120. A second adhesive layer 142 are laminated on the second copper trace layer 115 and the second stuffing layer 132 of the inner layer substrate 120, a second copper film 152 is laminated on the second adhesive layer 142. The second adhesive layer 142 is arranged between the second copper film 152 and the inner layer substrate 120.

In an alternative embodiment, to reinforce the combination of the first, second adhesive layer 141, 152 and the inner layer substrate 120, before laminating the first adhesive layer 141 and the second adhesive layer 142, the first surface 1111 is exposed in the gaps between the first copper trace layer 114, the surface of the first copper trace layer 114, the surface of the first stuffing layer 131, the second surface 1112 is exposed in the gaps between the second copper trace layer 115, surfaces of the second copper trace layer 115 and surface of the second stuffing layer 132 can be roughened by black oxidation.

The first adhesive layer 141, the first copper film 151, the second adhesive layer 142 and the second copper film 152 can be formed on the inner substrate 120 simultaneously or in a predetermined order. That is, the second adhesive layer 142 and the second copper film 152 can be laminated on the inner substrate 120 after the first adhesive layer 141 and the first copper film 151 is laminated on the inner layer substrate 120.

When laminating, the gaps of the first copper trace layer 114 have been filled with the first stuffing layer 131, the first adhesive layer 141 does not need to fill the gaps of the first copper trace layer 114, thus after laminating the thickness of the entire first adhesive layer 141 is uniform. When laminating, the gaps of the first copper trace layer 115 have been filled by the second stuffing layer 132, the second adhesive layer 142 does not need to fill the gaps of the second copper trace layer 115, thus after laminating, the thickness of the entire second adhesive layer 142 is uniform.

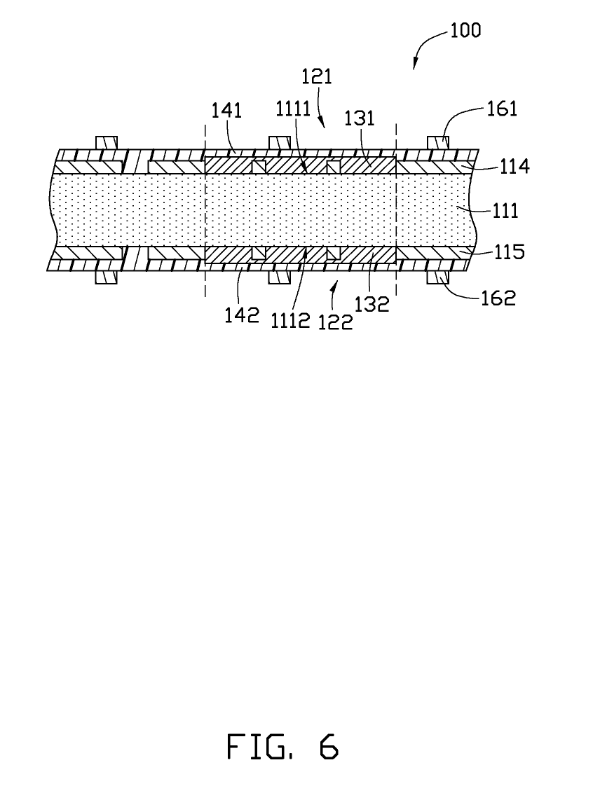

In Step 5, referring to FIG. 6, a third copper trace layer 161 is formed by removing part of first copper film 151. A fourth copper trace layer 162 are formed by removing part of second copper film 152. Thus, a printed circuit board 100 having four copper trace layers is obtained.

The third copper trace layer 161 and the fourth copper trace layer 61 can be formed by using a photolithography process and an etching process.

Referring to FIG. 6, the printed circuit board 100 includes the inner substrate 120, the first stuffing layer 131, the second stuffing layer 132, the first adhesive layer 141, the second adhesive layer 142, the numbers of third copper trace layer 161 and the numbers of second copper trace layer 162.

The inner layer substrate 120 includes the insulating layer 111, the numbers of first copper trace layer 114 formed on the first surface 1111 of the insulating layer 111, and the numbers of second copper trace layer 115 formed on the second surface 1112 of the insulating layer 111. The first surface 1111 includes a first low copper density region 121, the second surface 1112 includes a second low copper density region 122. In the first low copper density region 121, an area of the first surface 1111 covered by the first copper trace layer 114 is less than a percent of 60 percent of the entire area of the first low copper density region 121. In other words, when forming the first copper trace layer 114 on the first low copper density region 121, more than 40 percent of the first electrically layer 112 on the first low copper density region 121 is removed. In the second low copper density region 122, an area of the second surface 1112 covered by the second copper trace layer 115 is less than a percent of 60 percent of the entire area of the second low copper density region 122. In other words, when forming the second copper trace layer 115 on the second low copper density region 122, more than 40 percent of the second electrically conductive layer 113 on the second low copper density region 122 is removed.

The first stuffing layer 131 is at least formed on the first surface 1111 exposed to the gaps between the first copper trace layer 114. The first stuffing layer 131 can also be formed on the first surface 1111 exposed to the gaps between the first copper trace layer 114, and the surface of the first copper trace layer 114 in the first low copper density region 121. The second stuffing layer 132 is at least formed on the second surface 1112 exposed to the gaps between the second copper trace layer 115. The second stuffing layer 132 can also be formed on the second surface 1112 exposed to the gaps between the second copper trace layer 115 and the surface of the second copper trace layer 115 in the first low copper density region 121.

It is believed that the present embodiments and their advantages will be understood from the foregoing description, and it will be apparent that various changes may be made thereto without departing from the spirit and scope of the disclosure or sacrificing all of its material advantages, the examples hereinbefore described merely being preferred or exemplary embodiments of the disclosure.

1. A printed circuit board, comprising:
an inner layer substrate comprising an insulating layer and a patterned first copper trace layer, the insulating layer comprising a first surface, the first copper trace layer formed on the first surface, the first surface of the inner layer substrate comprising a localized low copper density region in which an area of portions of the first surface covered by the first copper trace layer is less than 60 percent of an area of the entire low copper density region;
a first stuffing layer formed on the low copper density region of the first surface ;
a first adhesive layer laminated on the first surface and covering the first copper trace layer and the first stuffing layer; and
a patterned second copper trace layer formed on the first adhesive layer.

2. The printed circuit board of claim 1, wherein a thickness of the first stuffing layer is substantially equal to a thickness of the first copper trace layer.

3. The printed circuit board of claim 1, wherein a thickness of the first stuffing layer is less than a thickness of the first copper trace layer.

4. The printed circuit board of claim 1, further comprising a second stuffing layer, a second adhesive layer, and a patterned fourth copper trace layer, the insulating layer comprising a second surface opposite to the first surface, the inner layer substrate further comprising a patterned third copper trace layer formed on the second surface, the second surface of the inner layer substrate comprising a localized low cooper density region in which an area of portions of the second surface covered by the third copper trace layer is less than 60% of an area of the localized low cooper density region of the second surface;
the second stuffing layer formed on the low cooper density region of the second surface;
the second adhesive layer laminated on the second surface and covering the second copper trace layer and the second stuffing layer; the fourth copper trace layer formed on the adhesive layer.

5. The printed circuit board of claim 4, wherein the thickness of the second stuffing layer is substantially equal to the thickness of the third copper trace layer.

6. The printed circuit board of claim 1, wherein the thickness of the second stuffing layer is less than the thickness of the third copper trace layer.

7. A method of manufacturing a printed circuit board, comprising:
providing a substrate, the substrate comprising an insulating layer and a copper layer, the insulating layer comprising a first surface, the copper layer formed on the first surface;
removing part of the copper layer thereby obtaining a patterned copper trace layer on the first surface, the first surface comprising a localized low copper density region in which an area of portions of the surface covered by the copper trace layer is less than 60 percent of an area of the low copper density f;
forming a stuffing layer on the low copper density region of the first surface;
laminating an adhesive layer on the first surface to cover the copper trace layer and the stuffing layer;
forming a patterned copper trace layer on the adhesive layer.

8. The method of claim 7, wherein the stuffing layer is formed by printing insulating ink on the low copper density region of the first surface.

9. The method of claim 7, wherein a thickness of the stuffing layer formed on the surface is equal to a thickness of the copper trace layer formed on the first surface.

10. The method of claim 7, wherein a thickness of the stuffing layer formed on the surface is less than a thickness of the copper trace layer formed on the first surface.

11. The method of claim 7, wherein the copper trace layer and exposed portions of the first surface in the low copper density region are roughened prior to forming the stuffing layer.

12. The method of claim 7, wherein the copper trace layer, exposed portions of the first surface, and the stuffing layer are roughened prior to the step of laminating the adhesive layer.
